(19) United States
(12) Patent Application Publication
(10) Pub. No.: US 2019/0088872 A1
(43) Pub. Date: Mar. 21, 2019

(54) STORAGE DEVICE AND METHOD FOR MANUFACTURING THE SAME

(71) Applicant: Toshiba Memory Corporation, Minato-ku (JP)

(72) Inventors: Yusuke Tanaka, Kawasaki (JP); Atsushi Hieno, Yokohama (JP)

(73) Assignee: Toshiba Memory Corporation, Minato-ku (JP)

(21) Appl. No.: 15/892,564

(22) Filed: Feb. 9, 2018

(30) Foreign Application Priority Data
Sep. 19, 2017 (JP) 2017-178985

(51) Int. Cl. H01L 45/00; H01L 27/24

(52) U.S. Cl. CPC H01L 45/14; H01L 45/08; H01L 45/1683; H01L 27/2481; H01L 45/1608; H01L 27/2436

(57) ABSTRACT

A storage device according to an embodiment includes a first conductive layer, a second conductive layer, and a resistance change layer. The resistance change layer is positioned between the first conductive layer and the second conductive layer. The resistance change layer including an organic compound. The organic compound has at least one first functional group selected from the group consisting of an amino group, a thiol group, a carboxy group, and an azide group, and the organic compound has one or less aromatic rings.

### CROSS-REFERENCE TO RELATED APPLICATION

This application is based upon and claims the benefit of priority from Japanese Patent Application No. 2017-178985, filed on Sep. 19, 2017, the entire contents of which are incorporated herein by reference.

### FIELD

Embodiments described herein relate generally to a storage device and a method for manufacturing the storage device.

### BACKGROUND

A Resistive Random Access Memory (ReRAM) makes a transition between a high resistance state and a low resistance state by applying a voltage to a resistance change layer of a memory cell. For example, if the high resistance state is defined as data “0” and the low resistance state as data “1”, the memory cell can store one bit data of “0” and “1”. It is desired to manufacture a Resistive Random Access Memory at low cost.

### BRIEF DESCRIPTION OF THE DRAWINGS

FIG. 1 is a schematic cross-sectional view of a memory cell of a storage device according to a first embodiment;

FIG. 2 is a block diagram of a memory cell array and peripheral circuits of the storage device according to the first embodiment;

FIGS. 3A, 3B, and 3C are schematic diagrams of a part of a memory cell array of the storage device according to the first embodiment;

FIGS. 4A, 4B, and 4C are schematic diagrams illustrating a method for manufacturing the storage device according to the first embodiment;

FIGS. 5A, 5B, and 5C are schematic diagrams illustrating a method for manufacturing the storage device according to the first embodiment;

FIGS. 6A, 6B, and 6C are schematic diagrams illustrating a method for manufacturing the storage device according to the first embodiment;

FIGS. 7A, 7B, and 7C are schematic diagrams illustrating a method for manufacturing the storage device according to the first embodiment;

FIGS. 8A, 8B, and 8C are schematic diagrams illustrating a method for manufacturing the storage device according to the first embodiment;

FIGS. 9A, 9B, and 9C are schematic diagrams indicating a method for manufacturing the storage device according to the first embodiment;

FIG. 10 is a block diagram of a storage device according to a second embodiment;

FIG. 11 is an equivalent circuit diagram of a memory cell array of the storage device according to the second embodiment;

FIGS. 12A and 12B are schematic cross-sectional diagrams of a part of the memory cell array of the storage device according to the second embodiment;

FIGS. 13A and 13B are schematic diagrams indicating a method for manufacturing the storage device according to the second embodiment;

FIGS. 14A and 14B are schematic diagrams indicating a method for manufacturing the storage device according to the second embodiment;

FIGS. 15A and 15B are schematic diagrams indicating a method for manufacturing the storage device according to the second embodiment;

FIGS. 16A and 16B are schematic diagrams indicating a method for manufacturing the storage device according to the second embodiment; and

FIGS. 17A and 17B are diagrams indicating results of a first example.

### DETAILED DESCRIPTION

A storage device according to an embodiment described herein includes: a first conductive layer; a second conductive layer; and a resistance change layer positioned between the first conductive layer and the second conductive layer, the resistance change layer including an organic compound, the organic compound having at least one first functional group selected from the group consisting of an amino group, a thiol group, a carboxy group, and an azide group, and the organic compound having one or less aromatic rings.

Embodiments of the present disclosure will be described below with reference to drawings. In description below, same or similar members will be denoted by same reference characters, and description of members already described will be appropriately omitted. In the present specification, the term “above” or “below” may be used for convenience. “Above” or “bottom” is a term indicating a relative positional relationship within a drawing and is not a term that defines a positional relationship with respect to gravity.

### First Embodiment

A storage device according to a first embodiment includes a first conductive layer, a second conductive layer, and a resistance change layer. The resistance change layer is positioned between the first conductive layer and the second conductive layer. The resistance change layer includes an organic compound. The organic compound has at least one first functional group selected from the group consisting of an amino group, a thiol group, a carboxy group, and an azide group, and the organic compound has one or less aromatic rings.

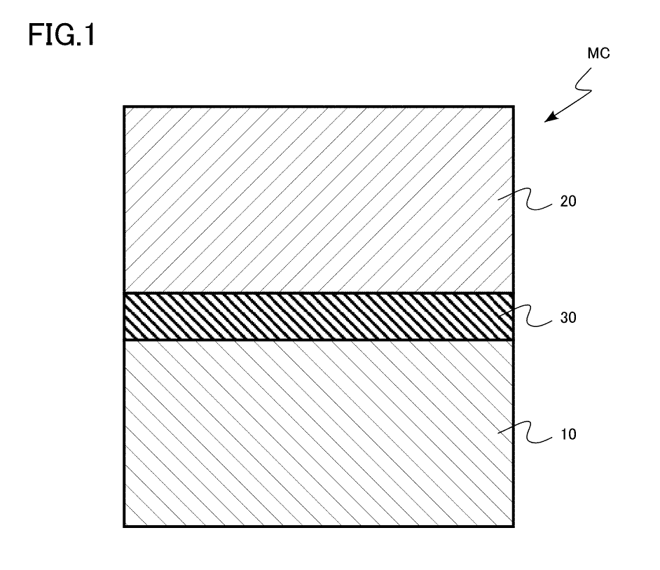

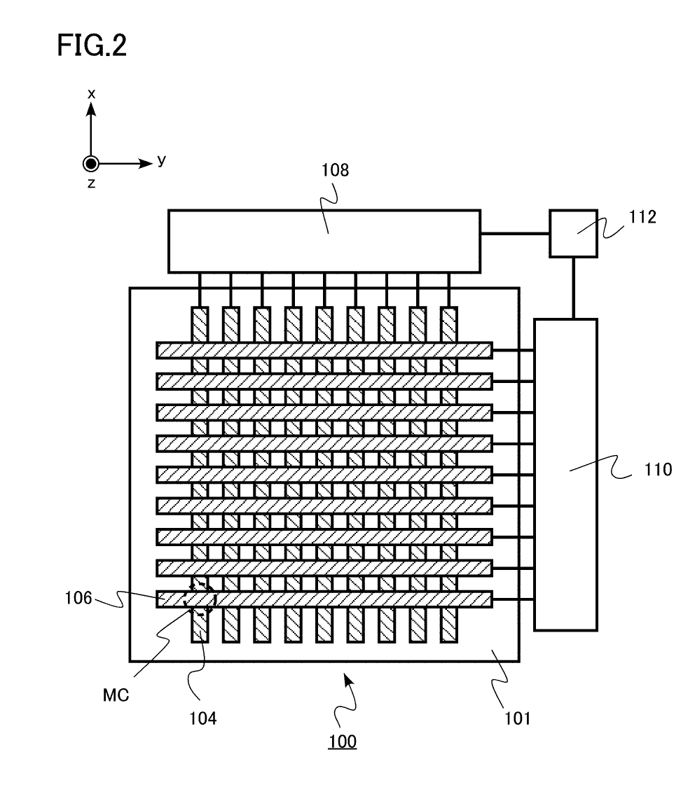

FIG. 1 is a schematic cross-sectional view of a memory cell MC of the storage device according to the first embodiment. FIG. 2 is a block diagram of a memory cell array 100 and peripheral circuits of the storage device according to the first embodiment. FIG. 1 indicates a cross section of one memory cell MC indicated by, for example, a dotted circle in the memory cell array 100 of FIG. 2.

The memory cell array 100 of the storage device according to the first embodiment includes, for example, a plurality of word lines 104 and a plurality of bit lines 106 crossing the word lines 104 over an insulating layer on a semiconductor substrate 101. The bit line 106 is provided above the word line 104. In addition, a first control circuit 108, a second control circuit 110, and a sense circuit 112 are provided as peripheral circuits around the memory cell array 100.

A plurality of memory cells MC is provided in a region where the word line 104 crosses the bit line 106. The storage device according to the first embodiment is a Resistive Random Access Memory having a cross point structure. The memory cell MC is a two-terminal resistance change element.

Each of the word lines 104 is connected to the first control circuit 108. Further, each of bit lines 106 is connected to the second control circuit 110. The sense circuit 112 is connected to the first control circuit 108 and the second control circuit 110.

For example, the first control circuit 108 and the second control circuit 110 have functions of selecting a desired memory cell MC, writing data to the memory cell, reading data of the memory cell, and erasing data of the memory cell. At the time of reading data, the data of the memory cell is read as the amount of current flowing between the word line 104 and the bit line 106. The sense circuit 112 has a function of determining the current amount and determining the polarity of the data. For example, “0” or “1” of data is determined.

The first control circuit 108, the second control circuit 110, and the sense circuit 112 include electronic circuits using semiconductor devices formed on the semiconductor substrate 101, for example.

As indicated in FIG. 1, the memory cell MC includes a lower electrode 10 (a first conductive layer), an upper electrode 20 (a second conductive layer), and a resistance change layer 30.

The lower electrode 10 is connected to the word line 104. The lower electrode 10 is, for example, a metal or a semiconductor. The lower electrode 10 is, for example, titanium nitride (TiN) or tungsten (W). The lower electrode 10 may be the word line 104.

The upper electrode 20 is connected to the bit line 106. The upper electrode 20 is, for example, a metal. The upper electrode 20 is, for example, a metal plating layer formed by an electroless plating method. The upper electrode 20 includes at least one metal selected from the group consisting of nickel (Ni), copper (Cu), cobalt (Co), gold (Au), zinc (Zn), tin (Sn), chromium (Cr), ruthenium (Ru), and silver (Ag). The upper electrode 20 may be the bit line 106.

The resistance change layer 30 is provided between the lower electrode 10 and the upper electrode 20. The resistance change layer 30 is an organic molecular layer. The resistance change layer 30 is, for example, a film used as a catalyst adsorption layer when the upper electrode 20 is formed by an electroless plating method.

The thickness of the resistance change layer 30 is, for example, 0.5 nm or more and five nm or less. The thickness of the resistance change layer 30 can be confirmed by, for example, a transmission electron microscope (TEM).

The resistance change layer 30 includes an organic compound having at least one first functional group selected from the group consisting of an amino group, a thiol group, a carboxy group, and an azide group, the organic compound having one or less aromatic ring. In the organic compound contained in the resistance change layer 30, the number of aromatic rings is 1 or 0. The organic compound contained in the resistance change layer 30 has a second functional group of, for example, a silanol group or an alkoxysilyl group.

The resistance change layer 30 includes, for example, an organic compound represented by one of the following formulas (1) to (6).

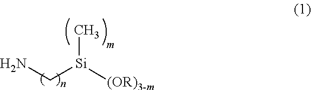

In the formula (1), n is an integer of one or more and eleven or less, m is an integer of zero or more and two or less, and R is any one of H, CH3, and CH₃CH₂.

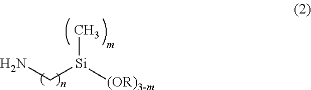

In the formula (2), n is an integer of one or more and eleven or less, m is an integer of zero or more and two or less, and R is any one of H, CH₃, and CH₃CH₂.

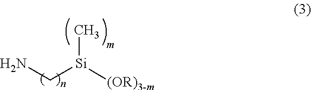

In the formula (3), n is an integer of one or more and five or less, m is an integer of zero or more and two or less, and R is any one of H, CH₃, and CH₃CH₂.

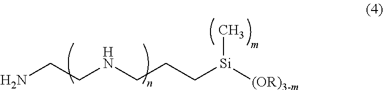

In the formula (4), n is an integer of zero or more and two or less, m is an integer of zero or more and two or less, and R is any one of H, CH₃, and CH₃CH₂.

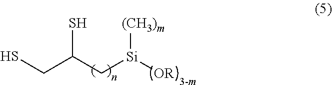

In the formula (5), n is an integer of one or more and six or less, m is an integer of zero or more and two or less, and R is any one of H, CH₃, and CH₃CH₂.

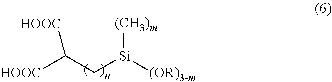

In the formula (6), n is an integer of one or more and 4 or less, m is an integer of zero or more and two or less, and R is any one of H, CH₃, and CH₃CH₂.

Further, the resistance change layer 30 includes, for example, an organic compound represented by the following formula (7).

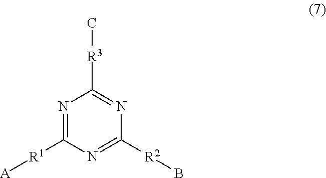

In the formula (7), A, B, and C may be functional groups. At least one of A, B, and C is at least one first functional group selected from the group consisting of an amino group, a thiol group, a carboxy group, and an azide group, and at least one of A, B, and C is a second functional group of either one of a silanol group and an alkoxysilyl group, and R¹, R² and R³ are arbitrarily present connecting groups.

By applying a voltage to the resistance change layer 30, the resistance change layer 30 changes from a high resistance state to a low resistance state or from the low resistance state to the high resistance state. The change from the high resistance state to the low resistance state is referred to as a set operation, for example. The change from the low resistance state to the high resistance state is referred to as a reset operation, for example. The voltage applied to the resistance change layer 30 in the case of changing from the high resistance state to the low resistance state is a set voltage and the voltage applied to the resistance change layer 30 in the case of changing the low resistance state to the high resistance state is referred to as a reset voltage.

For example, the high resistance state is defined as data “0”, and the low resistance state is defined as data “1”. The memory cell MC can store 1-bit data of “0” and “1”.

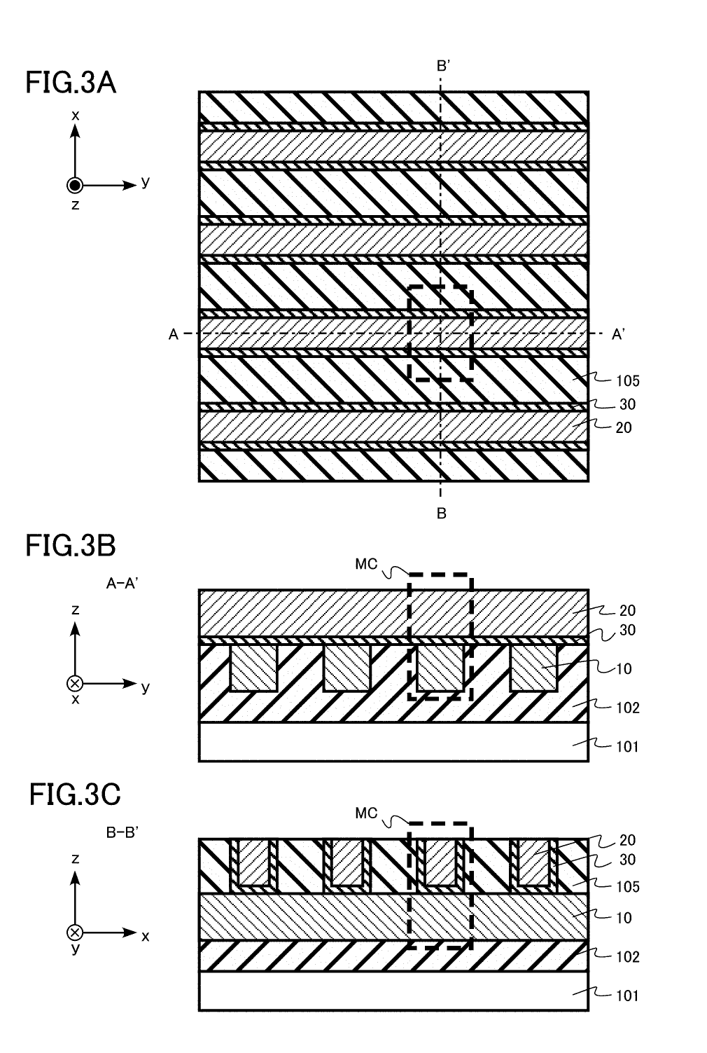

FIGS. 3A, 3B, and 3C are schematic diagrams of a part of the memory cell array 100 of the storage device according to the first embodiment. FIG. 3A is a top view. FIG. 3B is a cross-sectional view taken along the A-A′ direction of FIG. 3A. FIG. 3C is a cross-sectional view taken along the B-B′ direction of FIG. 3A.

FIGS. 3A, 3B, and 3C indicate the case where the lower electrode 10 is the word line 104, and the upper electrode 20 is the bit line. The memory cell array 100 includes the semiconductor substrate 101, a first insulating layer 102, a second insulating layer 105, a lower electrode 10, the upper electrode 20, and the resistance change layer 30. In FIGS. 3A, 3B, and 3C, regions surrounded by broken lines are one memory cell MC.

The semiconductor substrate 101 is, for example, a silicon substrate. The first insulating layer 102 is provided over the semiconductor substrate 101. The first insulating layer 102 is, for example, silicon oxide.

The lower electrode 10 is provided in the first insulating layer 102. The lower electrode 10 extends in the x direction. The lower electrode 10 is, for example, a metal. The lower electrode 10 is, for example, a stacked film of titanium nitride and tungsten.

The second insulating layer 105 is provided on the first insulating layer 102 and on the lower electrode 10. The second insulating layer 105 is, for example, silicon oxide.

In the second insulating layer 105, the resistance change layer 30 and the upper electrode 20 are provided. The upper electrode 20 extends in the y direction. The upper electrode 20 is, for example, a metal. The upper electrode 20 is, for example, nickel.

The resistance change layer 30 is provided between the second insulating layer 105 and the upper electrode 20. The resistance change layer 30 is an organic molecular layer. A part of the resistance change layer 30 is provided between the lower electrode 10 and the upper electrode 20. A part of the resistance change layer 30 is in contact with the lower electrode 10.

Next, a storage device manufacturing method according to the first embodiment will be described. The method for manufacturing the storage device according to the first embodiment includes forming a conductive layer, forming a catalyst adsorption layer on a conductive layer, forming a catalyst layer on the catalyst adsorption layer, and forming a metal layer on the catalyst layer by an electroless plating method.

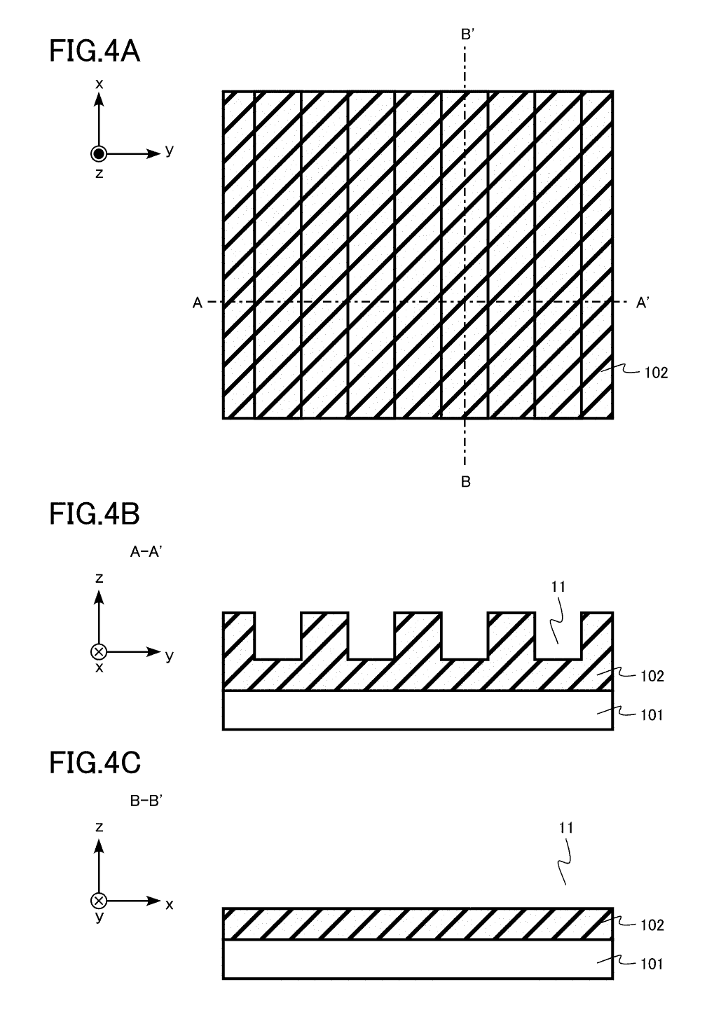

FIGS. 4A, 4B, 4C, 5A, 5B, 5C, 6A, 6B, 6C, 7A, 7B, 7C, 8A, 8B, 8C, 9A, 9B, and 9C are schematic diagrams indicating the storage device manufacturing method of the first embodiment. FIGS. 4A, 4B, 4C, 5A, 5B, 5C, 6A, 6B, 6C, 7A, 7B, 7C, 8A, 8B, 8C, 9A, 9B, and 9C indicates manufacturing methods for the storage device indicated in FIGS. 3A, 3B, and 3C.

The first insulating layer 102 is formed on the semiconductor substrate 101. Next, a groove 11 is formed in the first insulating layer 102 (FIGS. 4A, 4B, and 4C). The groove 11 extends in the x direction. For forming the groove 11, for example, known lithography and dry etching methods are used.

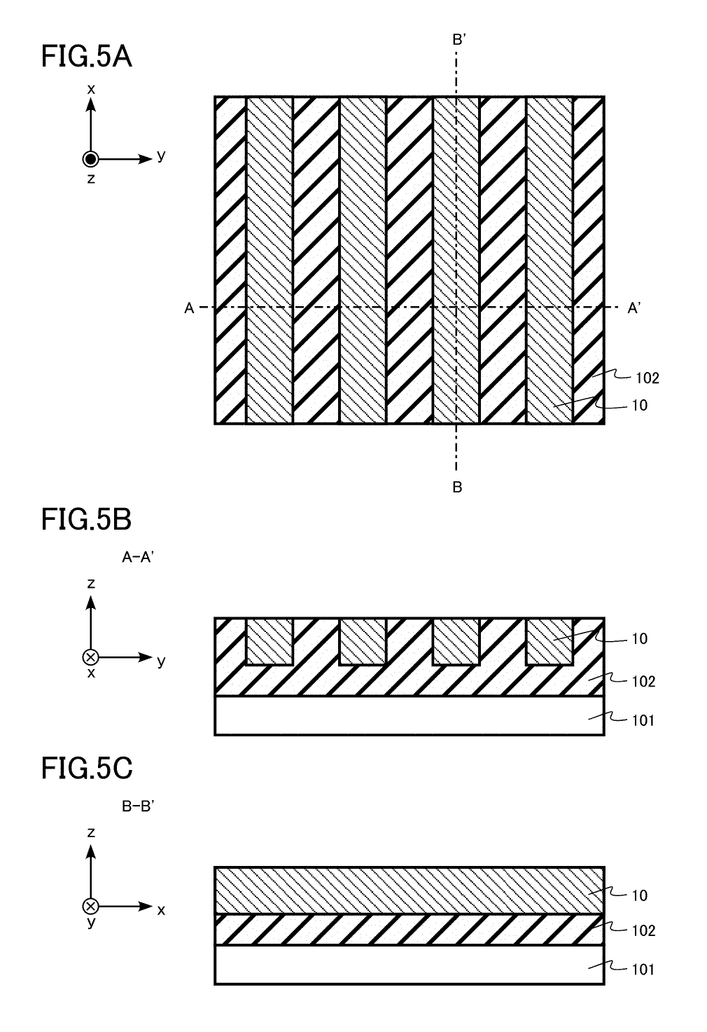

Next, the lower electrode 10 (conductive layer) is formed in the groove 11 (FIGS. 5A, 5B, and 5C). For forming the lower electrode 10, for example, known chemical vapor deposition (CVD) methods and chemical mechanical polishing (CMP) methods are used.

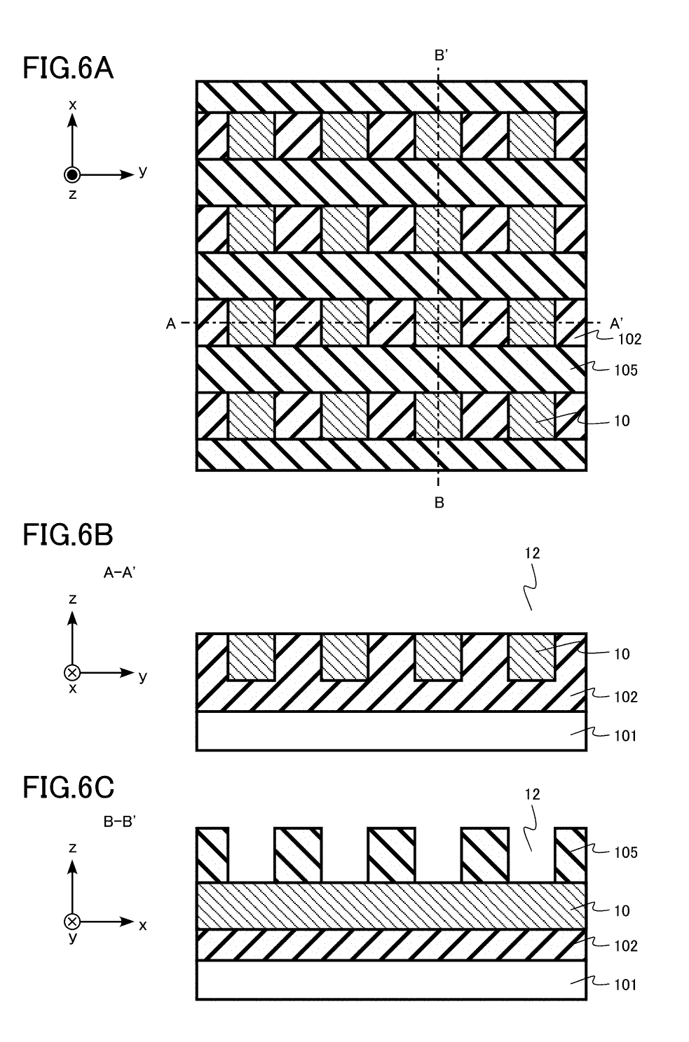

Next, the second insulating layer 105 is formed on the lower electrode 10 and on the first insulating layer 102. Next, a groove 12 is formed in the second insulating layer 105 (FIGS. 6A, 6B, and 6C). The groove 12 extends in the y direction. At the bottom of the groove 12, the surface of the lower electrode 10 is exposed. For forming the groove 12, for example, known lithography and dry etching methods are used.

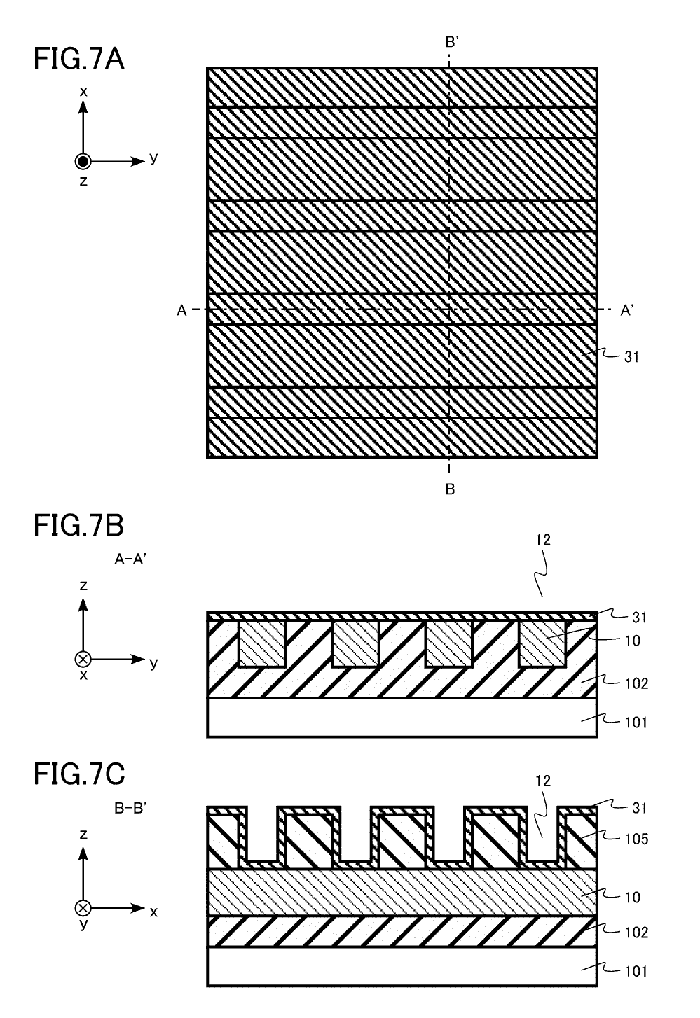

Next, a catalyst adsorption layer 31 is formed on the lower electrode 10 whose surface is exposed (FIGS. 7A, 7B, and 7C). The catalyst adsorption layer 31 is also formed on the second insulating layer 105. The thickness of the catalyst adsorption layer 31 is, for example, 0.5 nm or more and 5 nm or less.

The catalyst adsorption layer 31 is formed by bringing a surface of the lower electrode 10 into contact with a solution containing an organic compound. Contact between the surface of the lower electrode 10 and the solution containing an organic compound is performed by, for example, immersing the semiconductor substrate 101 in a solution containing an organic compound. Alternatively, a solution containing an organic compound is applied onto the lower electrode 10 and the second insulating layer 105. A contact time between the surface of the lower electrode 10 and the solution containing an organic compound is, for example, one minute or less.

A solution for forming the catalyst adsorption layer 31 includes an organic compound having at least one first functional group selected from the group consisting of an amino group, a thiol group, a carboxy group, and an azide group and the organic compound having one or less aromatic ring. The organic compound contained in the solution has one or zero aromatic ring. The organic compound contained in the resistance change layer 30 has a second functional group of, for example, a silanol group or an alkoxysilyl group.

The solution for forming the catalyst adsorption layer 31 includes, for example, an organic compound represented by any one of the following formulas (1) to (6).

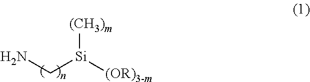

In the formula (1), n is an integer of one or more and eleven or less, m is an integer of zero or more and two or less, and R is any one of H, CH3, and CH₃CH₂.

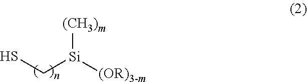

In the formula (2), n is an integer of one or more and eleven or less, m is an integer of zero or more and two or less, and R is any one of H, CH₃, and CH₃CH₂.

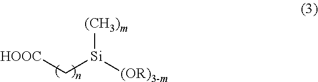

In the formula (3), n is an integer of one or more and five or less, m is an integer of zero or more and two or less, and R is any one of H, CH₃, and CH₃CH₂.

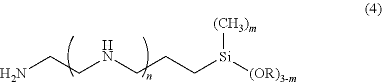

In the formula (4), n is an integer of zero or more and two or less, m is an integer of zero or more and two or less, and R is any one of H, CH₃, and CH₃CH₂.

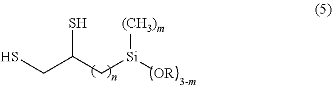

In the formula (5), n is an integer of one or more and six or less, m is an integer of zero or more and two or less, and R is any one of H, CH₃, and CH₃CH₂.

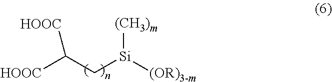

In the formula (6), n is an integer of one or more and 4 or less, m is an integer of zero or more and two or less, and R is any one of H, CH₃, and CH₃CH₂.

Further, the resistance change layer 30 includes, for example, an organic compound represented by the following formula (7).

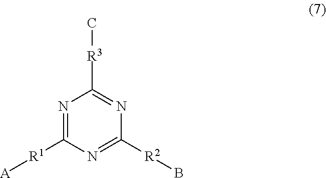

In the formula (7), at least one of A, B, and C is at least one first functional group selected from the group consisting of an amino group, a thiol group, a carboxy group, and an azide group, and at least one is a second functional group of a silanol group or an alkoxysilyl group, and R¹, R² and R³ are arbitrarily present connecting groups.

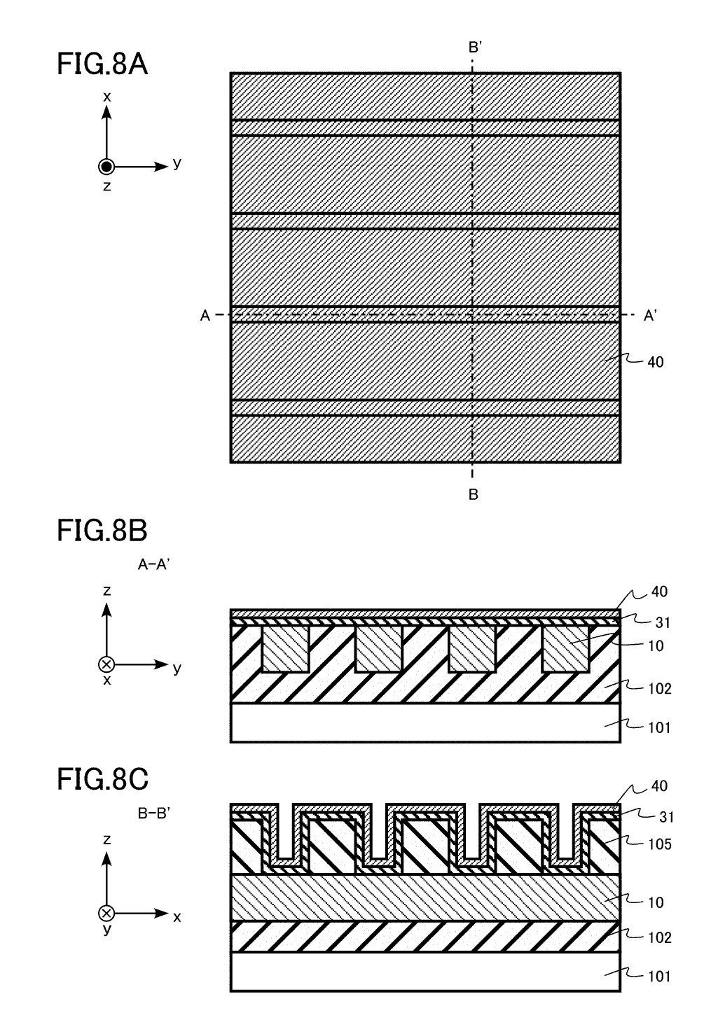

Next, a catalyst layer 40 is formed on the catalyst adsorption layer 31 (FIGS. 8A, 8B, and 8C). The catalyst layer 40 is formed by adsorbing a plating catalyst on the catalyst adsorption layer 31.

The plating catalyst is not particularly limited as long as it is a catalyst for electroless plating. For example, it is possible to use palladium (Pd), silver (Ag), copper (Cu), gold (Au), and platinum (Pt).

The catalyst layer 40 is formed by bringing a solution containing the plating catalyst into contact with a surface of the catalyst adsorption layer 31. A contact time between the surface of the catalyst adsorption layer 31 and the solution containing the plating catalyst is, for example, one minute or less.

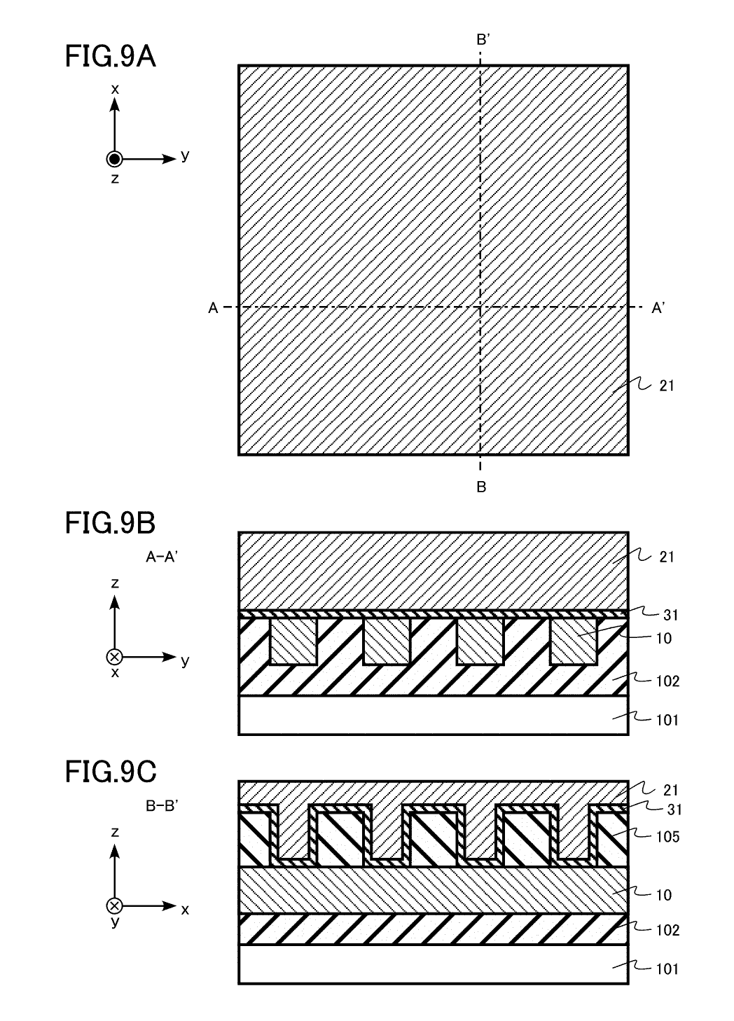

Next, a metal layer 21 is formed on the catalyst layer 40 by an electroless plating method (FIGS. 9A, 9B, and 9C). In the metal layer 21, a groove formed in the second insulating layer 105 is buried with the metal layer 21. In FIGS. 9A, 9B, and 9C, illustration of the catalyst layer 40 is omitted.

The material of the metal layer 21 is, for example, nickel (Ni), copper (Cu), cobalt (Co), gold (Au), zinc (Zn), tin (Sn), chromium (Cr), ruthenium (Ru), and Silver (Ag).

The metal layer 21 is formed by immersing the semiconductor substrate 101 in a plating solution. The plating solution contains, for example, a metal ion for forming the metal layer 21, a reducing agent, and a stabilizer for stabilizing the metal ion. The immersion time of the semiconductor substrate 101 into the plating solution is, for example, two minutes or less.

Next, the metal layer 21 on the second insulating layer 105 is removed, and the upper electrode 20 is formed. For removing the metal layer 21 on the second insulating layer 105, for example, a known CMP method is used. The catalyst adsorption layer 31 used in the electroless plating method becomes the resistance change layer 30.

Through the above-described manufacturing method, the storage device of the first embodiment indicated in FIGS. 3A, 3B, and 3C is manufactured.

Functions and effects according to the first embodiment will be described below.

In order to reduce the cost of a semiconductor device, it is desired to manufacture a Resistive Random Access Memory at low cost.

Various materials have been proposed as the resistance change layer of the Resistive Random Access Memory in which the resistance state is changed by applying a voltage. These materials include such as a metal oxide layer, a semiconductor film layer, and a stacked structure thereof. The metal oxide layer and the semiconductor layer are formed, for example, by using such as a sputtering method, a CVD method, and an ALD (Atomic Layer Deposition) method.

In the sputtering method, the CVD method, or the ALD method, the process throughput is not necessarily high, and the manufacturing cost of the Resistive Random Access Memory tends to increase. In particular, when a stacked structure in which a plurality of layers is stacked is used for the resistance change layer, process steps corresponding to the number of the stacked layers are required, and manufacturing cost of the Resistive Random Access Memory increases.

In addition, for example, when the sputtering method is used for forming the resistance change layer, the step coverage of the film is poor, and it becomes difficult to form the resistance change layer in fine grooves or holes, for example. In addition, for example, when the CVD method is used for forming the resistance change layer, the process temperature increases, and there is a possibility that the material and the element characteristics of the Resistive Random Access Memory may degrade.

Further, the metal layer included in the upper electrode 20 may also be formed by, for example, such as the sputtering method, the CVD method, or the ALD method. When such as the sputtering method, the CVD method, or the ALD method is used, the same problem as in the case of forming the resistance change layer occurs.

The resistance change layer 30 of the first embodiment is an organic molecular layer. The organic molecular layer is the catalyst adsorption layer 31 used for forming the upper electrode 20 by an electroless plating method.

It is considered that the resistance change layer 30 of the first embodiment results in a low resistance state since filaments of metal ions are formed in an organic molecular layer by applying a voltage. The organic molecular layer functions as an insulator without the filaments of metal ions in the high resistance state.

In the storage device of the first embodiment, the catalyst adsorption layer 31 is the resistance change layer 30. Therefore, the resistance change layer 30 and the upper electrode 20 can be simultaneously formed at the time of forming the upper electrode 20 by an electroless plating method. Therefore, the number of process steps is reduced, and the manufacturing cost of the Resistive Random Access Memory can be reduced.

Further, the electroless plating method is a low cost wet process unlike such as a sputtering method, a CVD method, and an ALD method. Therefore, the process cost is reduced, and the manufacturing cost of the Resistive Random Access Memory can be suppressed.

Further, the electroless plating method is superior to the step coverage of the film, for example, as compared with the sputtering method. Therefore, it is easy to form the resistance change layer 30 in fine grooves or holes. Further, for example, as compared with the CVD method, since the process temperature is low, it is possible to suppress degradation of materials and element characteristics of the Resistive Random Access Memory.

Further, by using the electroless plating method, it is possible to use a metal material, for example, gold (Au) or silver (Ag), which is difficult to form by a method other than the electroless plating method.

The organic compound contained in the resistance change layer 30 of the first embodiment and the organic compound in the solution forming the catalyst adsorption layer 31 preferably have at least one first functional group selected from the group consisting of an amino group, a thiol group, a carboxy group, and an azide group. By having the first functional group, the function of adsorbing a catalyst is developed.

The number of aromatic rings contained in the organic compound is preferably one or less. When the number of the aromatic rings is two or more, the molecular size of the organic compound becomes too large, and uniform formation of the catalyst adsorption layer 31 may be hindered.

In addition, it is preferable that the organic compound has a second functional group of either a silanol group or an alkoxysilyl group. By having the second functional group, the adhesion of the catalyst adsorption layer 31 with respect to an underlying layer is improved.

In addition, the organic compound is preferably an organic compound represented by the above formulas (1) to (7). Particularly superior resistance change characteristics are realized by using the organic compounds represented by the above formulas (1) to (7).

The thickness of the resistance change layer 30 is preferably, for example, 0.5 nm or more and five nm or less, and more preferably 0.5 nm or more and two nm or less. When the thickness is below the above range, it is difficult to form the uniform catalyst adsorption layer 31. Further, the resistance of the resistance change layer 30 in a high resistance state may not sufficiently increase. If the thickness exceeds the above range, peeling of the catalyst adsorption layer 31 may occur. Further, the resistance of the resistance change layer 30 in a low resistance state may not be sufficiently lowered.

As described above, according to the first embodiment, a Resistive Random Access Memory manufactured at low cost is realized. Further, it is possible to manufacture the Resistive Random Access Memory at low cost.

### Second Embodiment

A storage device of a second embodiment is different from that of the first embodiment in that the memory cell array has a three-dimensional structure. Therefore, a part of description of contents already described in the first embodiment will be omitted.

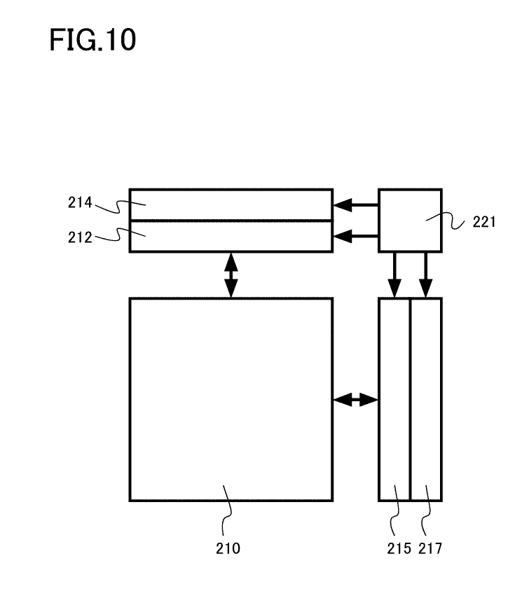

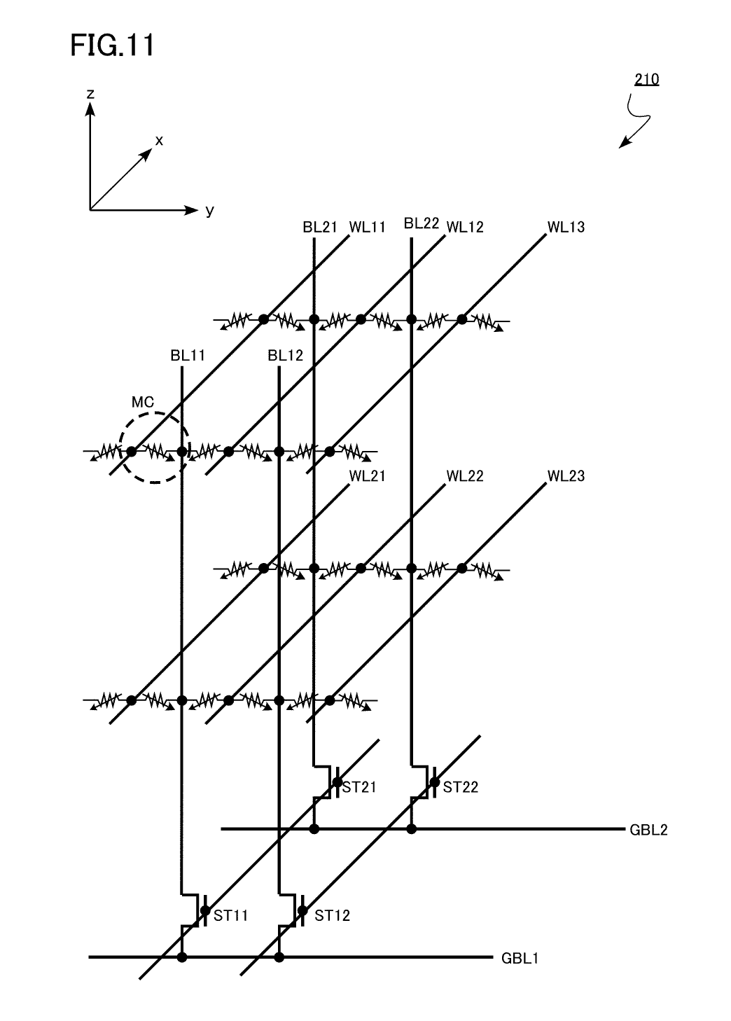

FIG. 10 is a block diagram of the storage device according to the second embodiment. FIG. 11 is an equivalent circuit diagram of the memory cell array of the storage device according to the second embodiment. FIG. 11 schematically indicates a wiring structure in the memory cell array. A memory cell array 210 of the second embodiment has a three-dimensional structure in which memory cells MC are three-dimensionally disposed.

As indicated in FIG. 10, the storage device includes the memory cell array 210, a word line driver circuit 212, a row decoder circuit 214, a sense amplifier circuit 215, a column decoder circuit 217, and a control circuit 221.

In addition, as indicated in FIG. 11, a plurality of memory cells MC is three-dimensionally disposed in the memory cell array 210. In FIG. 11, a region surrounded by a broken line is one memory cell MC.

The memory cell array 210 includes, for example, a plurality of word lines WL (WL11, WL12, WL13, WL21, WL22, and WL23) and a plurality of bit lines BL (BL11, BL12, BL21, and BL22). The word line WL extends in the x direction. The bit line BL extends in the z direction. The word line WL crosses the bit line BL vertically. The memory cells MC are disposed at intersections of the word lines WL and the bit lines BL.

A plurality of the word lines WL is electrically connected to the row decoder circuit 214. A plurality of the bit lines BL is connected to the sense amplifier circuit 215. Selection transistors ST (ST11, ST21, ST12, and ST22) and global bit lines GBL (GBL1 and GBL2) are provided between a plurality of the bit lines BL and the sense amplifier circuit 215.

The row decoder circuit 214 has a function of selecting the word line WL according to the input row address signal. The word line driver circuit 212 has a function of applying a predetermined voltage to the word line WL selected by the row decoder circuit 214.

The column decoder circuit 217 has a function of selecting the bit line BL according to the input column address signal. The sense amplifier circuit 215 has a function of applying a predetermined voltage to the bit line BL selected by the column decoder circuit 217. In addition, the sense amplifier circuit 215 has a function of amplifying by detecting a current flowing between the selected word line WL and the selected bit line BL.

The control circuit 221 has a function of controlling the word line driver circuit 212, the row decoder circuit 214, the sense amplifier circuit 215, the column decoder circuit 217, and other circuits (not illustrated).

Circuits such as the word line driver circuit 212, the row decoder circuit 214, the sense amplifier circuit 215, the column decoder circuit 217, and the control circuit 221 include, for example, a transistor and a wiring layer using a semiconductor layer (not illustrated).

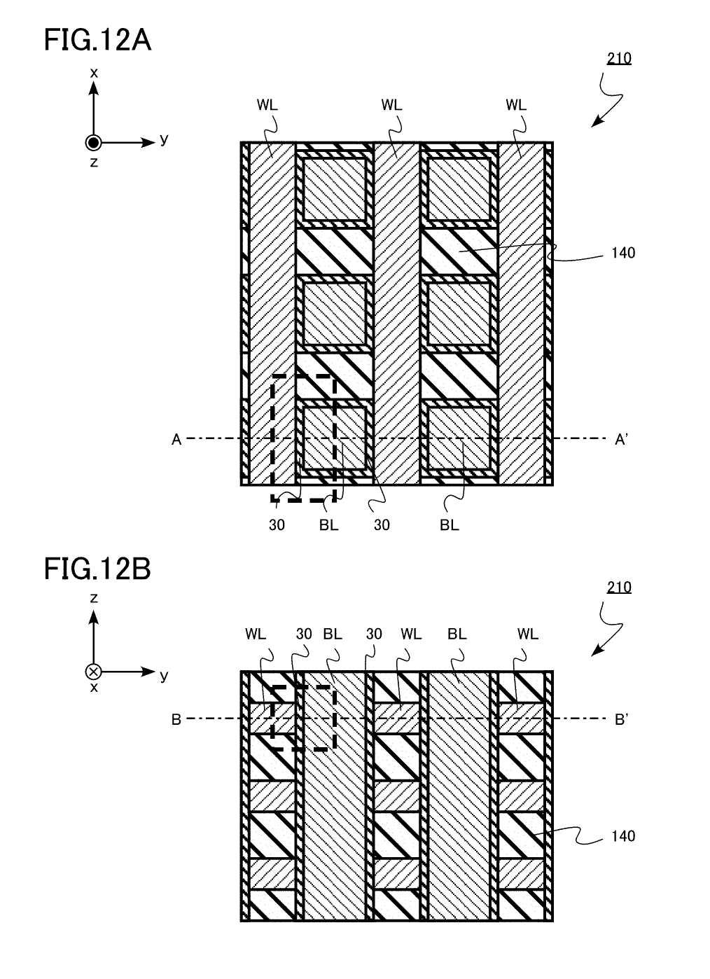

FIGS. 12A and 12B are schematic diagrams of a part of the memory cell array 210 of the storage device of the second embodiment. FIG. 12A is a sectional diagram of the memory cell array 210 taken along line xy. FIG. 12B is a cross-sectional diagram of the memory cell array 210 taken along line yz. FIG. 12A is a cross-sectional diagram taken along line BB′ of FIG. 12B. FIG. 12B is a cross-sectional diagram taken along line AA′ of FIG. 12A. In FIGS. 12A and 12B, a region surrounded by a broken line is one memory cell MC.

The memory cell array 210 includes a plurality of the word lines WL (first conductive layers) and a plurality of the bit lines BL (second conductive layers). Further, the resistance change layer 30 and an interlayer insulating layer 140 are provided.

The word lines WL are alternately stacked in the z direction with the interlayer insulating layer 140. The word line WL extends in the x direction.

The word line WL is, for example, a metal or a semiconductor. The word line WL is made of, for example, titanium nitride or tungsten. Alternatively, the word line WL has a stacked structure of titanium nitride and tungsten.

The bit line BL is provided between the word lines WL. The bit line BL extends in the z direction.

The bit line BL is, for example, a metal. The bit line BL is, for example, a metal plating layer formed by an electroless plating method. The bit line BL includes at least one metal selected from the group consisting of nickel (Ni), copper (Cu), cobalt (Co), gold (Au), zinc (Zn), tin (Sn), chromium (Cr), ruthenium (Ru), and silver (Ag).

The resistance change layer 30 is provided between the word line WL and the bit line. A structure similar to that of the resistance change layer 30 of the first embodiment is applied to the resistance change layer 30.

Next, a storage device manufacturing method according to the second embodiment will be described. In the method for manufacturing a storage device according to the second embodiment, an opening portion is formed on a stacked body in which conductive layers and insulating layers are alternatively stacked. The opening portion penetrates the insulating layers in a stacking direction of the stacked body, and the conductive layer is exposed on a side surface of the opening portion. Further, in the manufacturing method, a catalyst adsorption layer is formed by bringing the side surface of the opening portion into contact with a solution containing an organic compound, a catalyst layer is formed on the catalyst adsorption layer, and a metal layer is formed on the catalyst layer by an electroless plating method.

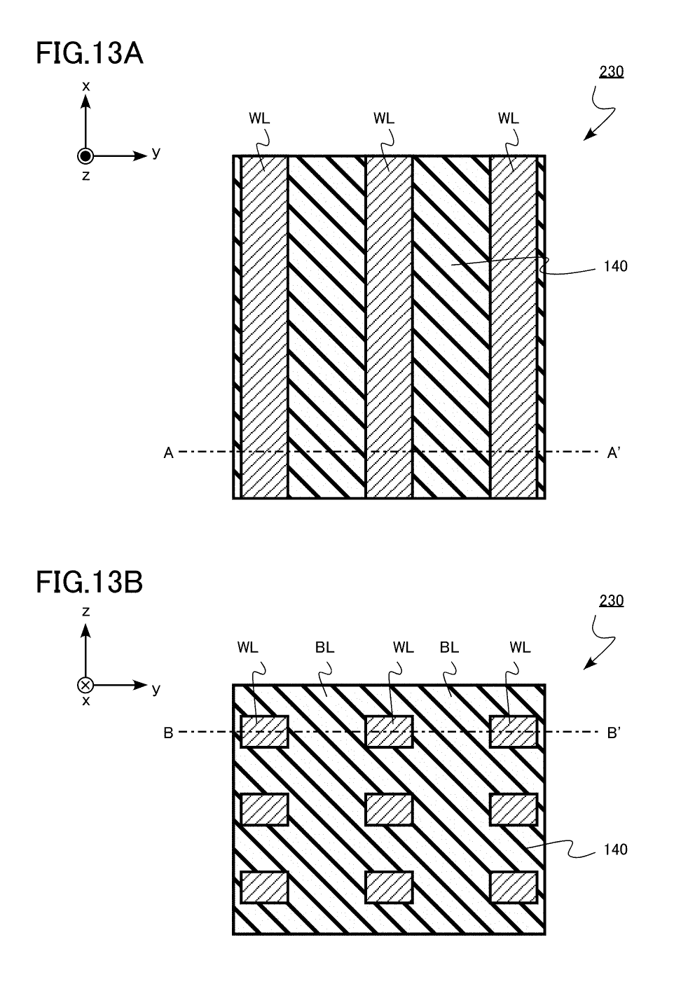

FIGS. 13A, 13B, 14A, 14B, 15A, 15B, 16A, and 16B are schematic cross-sectional diagrams indicating a method for manufacturing the storage device of the first embodiment. FIGS. 13A, 13B, 14A, 14B, 15A, 15B, 16A, and 16B indicate a method for manufacturing the storage device indicated in FIGS. 12A and 12B.

First, a stacked body 230 in which the word lines WL (conductive layers) and the interlayer insulating layers 140 (insulating layers) are alternately stacked in the z direction is formed (FIGS. 13A and 13B). The stacked body 230 is formed by using, for example, a known CVD method, a lithography method, and a dry etching method.

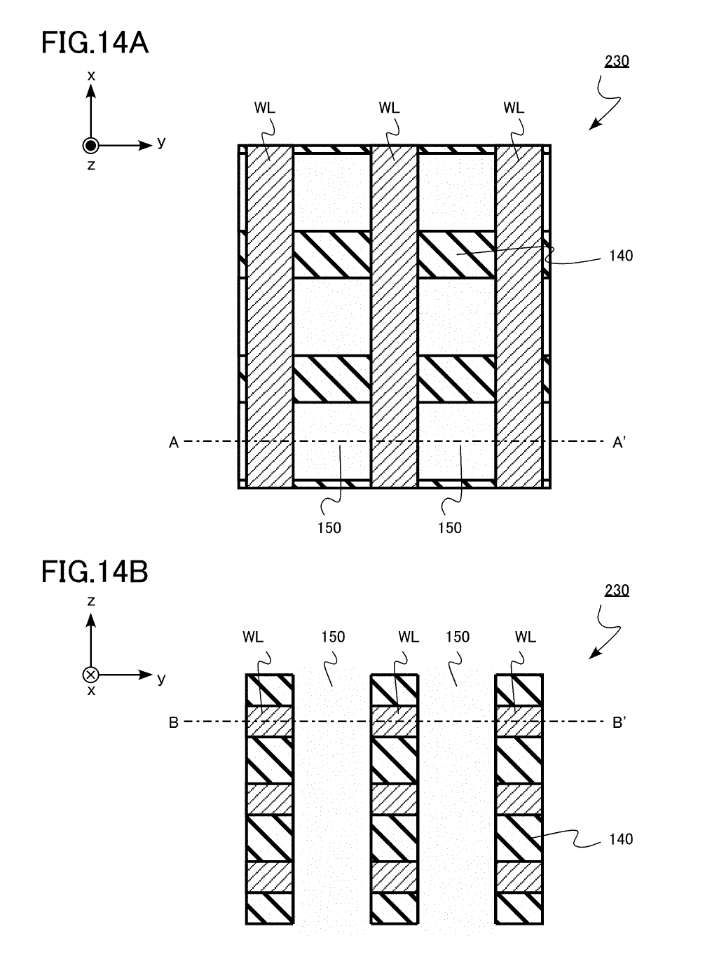

Next, the stacked body 230 is provided with an opening portion 150 penetrating the interlayer insulating layer 140 in the z direction which is the stacking direction of the stacked body 230 (FIGS. 14A and 14B). The word line WL is exposed on the side surface of the opening portion 150.

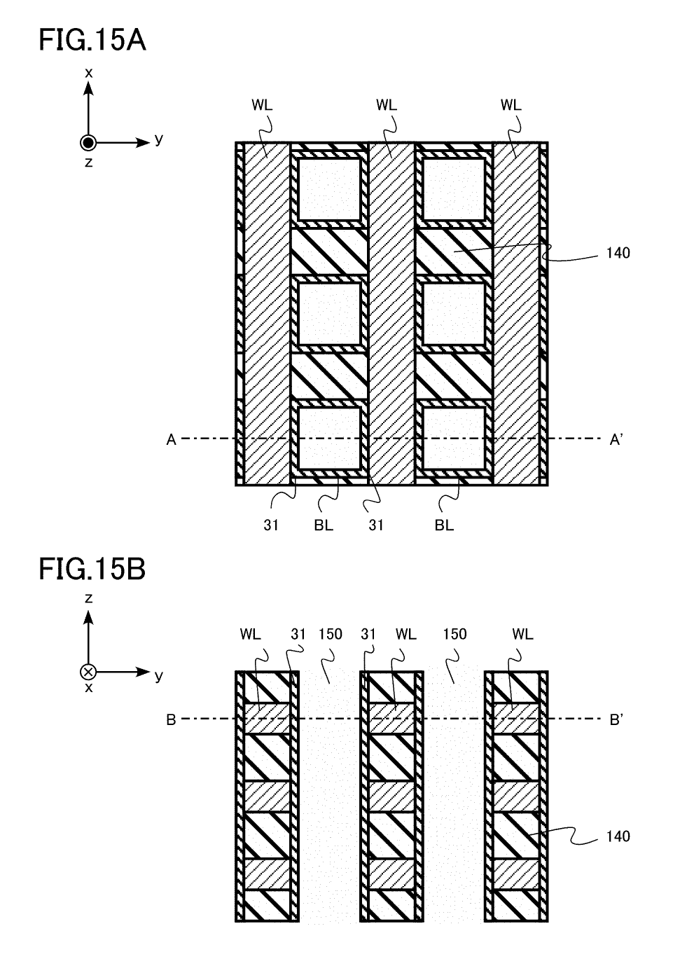

Next, a solution containing an organic compound is brought into contact with the side surface of the opening portion 150 to form the catalyst adsorption layer 31 (FIGS. 15A and 15B). The catalyst adsorption layer 31 is formed. A configuration of the catalyst adsorption layer 31 is the same as the configuration of the first embodiment.

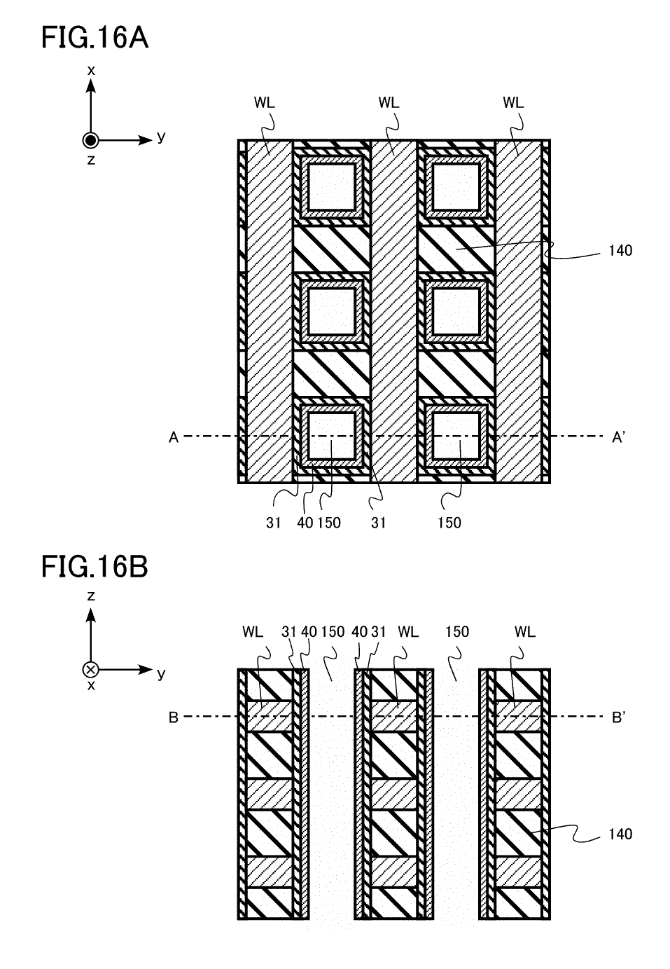

Next, a catalyst layer 40 is formed on the catalyst adsorption layer 31 (FIGS. 16A and 16B). A configuration of the catalyst layer 40 is the same as the configuration of the first embodiment.

Next, a metal layer is formed on the catalyst layer 40 by an electroless plating method. The configuration of the metal layer is the same as that of the metal layer 21 of the first embodiment. The opening portion 150 is buried with the metal layer and becomes the bit line BL. The catalyst adsorption layer 31 becomes the resistance change layer 30.

Through the above-described manufacturing method, the storage device of the second embodiment indicated in FIGS. 12A and 12B is manufactured.

In the Resistive Random Access Memory having a three-dimensional structure, it is necessary to form the resistance change layer 30 and the metal wiring layer in a groove or a hole having a high aspect ratio like the opening portion 150 indicated in FIGS. 14A and 14B. In the manufacturing method according to the second embodiment, since the electroless plating method having excellent step coverage is used, it is possible to form the resistance change layer 30 and the metal wiring layer also in the groove or the hole having a high aspect ratio.

According to the second embodiment, similarly to the first embodiment, a Resistive Random Access Memory manufactured at low cost is realized. Further, it is possible to manufacture the Resistive Random Access Memory at low cost. Furthermore, by providing a three-dimensional structure, it is possible to obtain an effect that the degree of integration of the Resistive Random Access Memory is improved.

### EXAMPLES

First and second examples will be described below.

### First Example

A structure according to the second embodiment has been prepared by the manufacturing method according to the second embodiment. A first conductive layer is formed in an insulating layer of silicon oxide. The first conductive layer has a stacked structure of titanium nitride and tungsten. By using a dry etching method, an opening portion is formed. The opening portion penetrates the insulating layer, and the first conductive layer is exposed on a side surface of the opening portion.

A catalyst adsorption layer is formed by rinsing in pure water for 15 seconds after immersing in an aqueous solution of 3-aminopropyltrimethoxysilane at a concentration of 0.1% for 30 seconds. The aqueous solution of 3-aminopropyltrimethoxysilane is an organic compound represented by the above formula (1), in the case of n=3, m=0, and R=CH₃.

Next, 1wt % palladium chloride hydrochloric acid solution is immersed in a palladium solution diluted in 1% aqueous solution for 30 seconds and then rinsed in pure water for 15 seconds to form a metal catalyst layer.

Next, using a NiB plating solution with pH 6.5 using dimethylamine borane as a reducing agent, electroless plating treatment is performed at a plating temperature of 62° C. for 80 seconds to form a nickel layer. The nickel layer is the second conductive layer.

Current voltage characteristics are evaluated by fixing the first conductive layer to the ground and changing the voltage of the second conductive layer.

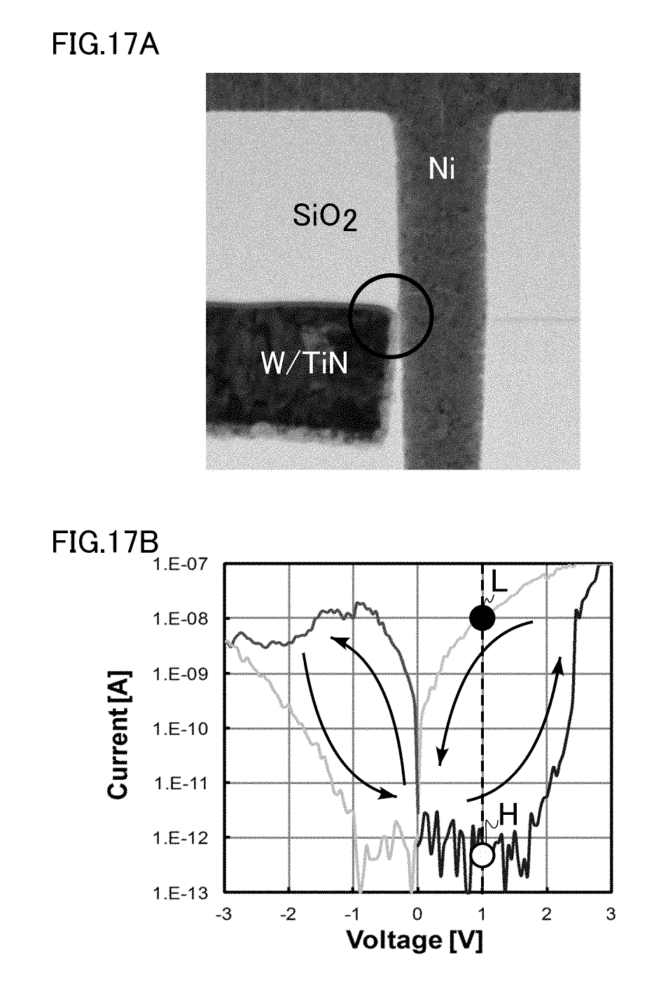

FIGS. 17A and 17B are diagrams indicating results of the first example. FIG. 17A is a sectional TEM photograph. FIG. 17B indicates current-voltage characteristics.

In FIG. 17A, a region surrounded by a circle is a memory cell. By an electroless plating method, an opening portion with a high aspect ratio is filled with nickel without voids.

As is clear from FIG. 17B, it can be found that by changing the voltage, a high resistance state (H, the white circle, in FIG. 17B) and a low resistance state (L, the solid circle, in FIG. 17B) are realized. That is, it became clear that set operation and reset operation are realized. Therefore, it has been clarified that the Resistive Random Access Memory can be realized with the structure manufactured by the manufacturing method according to the second embodiment.

### Second Example

The same structure as in the first example is prepared except that the aqueous solution for forming a catalyst adsorption layer is an aqueous triazine compound solution. The triazine compound aqueous solution contains the triazine compound represented by the above formula (7).

Further, in the second example, the same current-voltage characteristics as in the first example have been obtained.

In the first embodiment, the case where the cross-point structure of the memory cell array 100 is only one layer has been described. However, it is also possible to have a three-dimensional structure in which a plurality of the memory cell arrays 100 of the first embodiment is stacked.

In the first and second embodiments, the case where the metal plating layer by the electroless plating method is applied to the second conductive layer has been described as an example. However, a metal plating layer by the electroless plating method can be applied to the first conductive layer. For example, in the second embodiment, the metal plating layer by the electroless plating method is applied to the bit line BL as an example. However, it is also possible to form the bit line BL first and apply the metal plating layer by the electroless plating method to the word line WL.

In addition, in the first or second embodiment, a selector may be provided in addition to the resistance change layer 30 between the word line and the bit line. The selector is, for example, a unidirectional diode or a bidirectional diode. Bidirectional diodes are elements with nonlinearity in current-voltage characteristics regardless of the voltage application direction. When the selector is provided between the word line and the bit line, the first conductive layer or the second conductive layer may be included in the selector.

In the first or second embodiment, between the first conductive layer and the resistance change layer 30 and between the second conductive layer and the resistance change layer 30, for example, a thin oxide layer in which a tunnel current flows, a nitride layer, and an oxynitride layer may be provided.

While certain embodiments have been described, these embodiments have been presented by way of example only, and are not intended to limit the scope of the inventions. Indeed, a storage device and a manufacturing method for the storage device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A storage device, comprising:
a first conductive layer;
a second conductive layer; and
a resistance change layer positioned between the first conductive layer and the second conductive layer, the resistance change layer including an organic compound, the organic compound having at least one first functional group selected from the group consisting of an amino group, a thiol group, a carboxy group, and an azide group, and the organic compound having one or less aromatic rings.

2. The storage device according to claim 1, wherein the organic compound has a second functional group, and the second functional group is one a silanol group and an alkoxysilyl group.

3. The storage device according to claim 2, wherein the organic compound is represented by any one of the following formulas (1) to (6),
in the following formula (1), n is an integer of one or more and eleven or less, m is an integer of zero or more and two or less, and R is any one of H, CH₃, and CH₃CH₂,
in the following formula (2), n is an integer of one or more and eleven or less, m is an integer of zero or more and two or less, and R is any one of H, CH₃, and CH₃CH₂,
in the following formula (3), n is an integer of one or more and five or less, m is an integer of zero or more and two or less, and R is any one of H, CH₃, and CH₃CH₂,
in the following formula (4), n is an integer of zero or more and two or less, m is an integer of zero or more and two or less, and R is any one of H, CH₃, and CH₃CH₂,
in the following formula (5), n is an integer of one or more and six or less, m is an integer of zero or more and two or less, and R is any one of H, CH₃, and CH₃CH₂, and
in the following formula (6), n is an integer of one or more and four or less, m is an integer of zero or more and two or less, and R is any one of H, CH3, and CH₃CH₂.

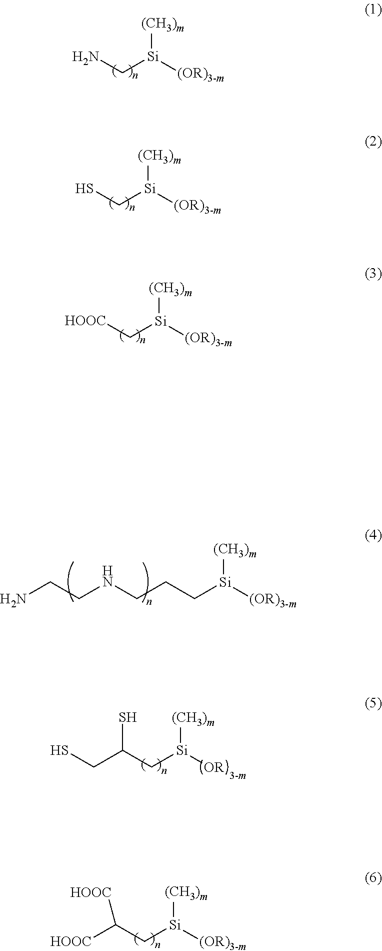

4. The storage device according to claim 2, wherein the organic compound is represented by the following formula (7), at least one of A, B, and C in the formula (7) is the first functional group, at least one of A, B, and C is the second functional group, and R¹, R², and R³ are arbitrarily present linking groups.

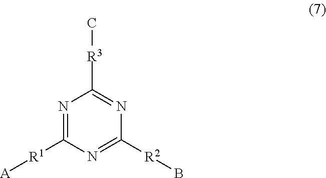

5. The storage device according to claim 1, wherein at least either one of the first conductive layer and the second conductive layer is a metal plating layer.

6. The storage device according to claim 1, wherein at least either of the first conductive layer and the second conductive layer includes at least one metal selected from the group consisting of nickel (Ni), copper (Cu), cobalt (Co), gold (Au), zinc (Zn), tin (Sn), chromium (Cr), ruthenium (Ru), and silver (Ag).

7. The storage device according to claim 1, wherein the resistance change layer has a thickness of 0.5 nm or more and 5 nm or less.

8. A method for manufacturing a storage device, comprising:
forming a conductive layer;
forming a catalyst adsorption layer on the conductive layer;
forming a catalyst layer on the catalyst adsorption layer; and
forming a metal layer on the catalyst layer by an electroless plating method.

9. The method for manufacturing a storage device according to claim 8, wherein the catalyst adsorption layer is formed by bringing the conductive layer into contact with a solution containing an organic compound in the forming the catalyst adsorption layer.

10. The method for manufacturing a storage device according to claim 9, wherein the organic compound has at least one first functional group selected from the group consisting of an amino group, a thiol group, a carboxy group, and an azide group, and the organic compound has one or less aromatic ring.

11. The method for manufacturing a storage device according to claim 10, wherein the organic compound has a second functional group, and the second functional group is one a silanol group and an alkoxysilyl group.

12. A method for manufacturing a storage device according to claim 10, wherein the organic compound is represented by any one of the following formulas (1) to (6),
in the following formula (1), n is an integer of one or more and eleven or less, m is an integer of zero or more and two or less, and R is any one of H, CH₃, and CH₃CH₂,
in the following formula (2), n is an integer of one or more and eleven or less, m is an integer of zero or more and two or less, and R is any one of H, CH₃, and CH₃CH₂,
in the following formula (3), n is an integer of one or more and five or less, m is an integer of zero or more and two or less, and R is any one of H, CH₃, and CH₃CH₂,
in the following formula (4), n is an integer of zero or more and two or less, m is an integer of zero or more and two or less, and R is any one of H, CH₃, and CH₃CH₂,
in the following formula (5), n is an integer of one or more and six or less, m is an integer of zero or more and two or less, and R is any one of H, CH₃, and CH₃CH₂, and
in the following formula (6), n is an integer of one or more and four or less, m is an integer of zero or more and two or less, and R is any one of H, CH3, and CH₃CH₂.

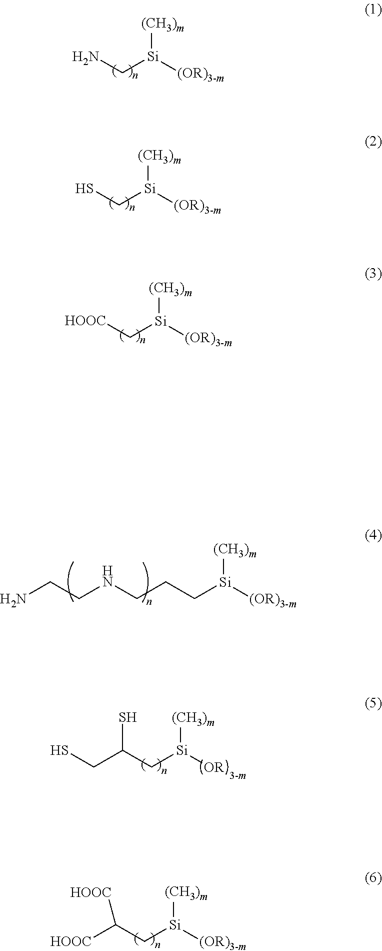

13. The method for manufacturing a storage device according to claim 11, wherein the organic compound is represented by the following formula (7), at least one of A, B, and C in the formula (7) is the first functional group, at least one of A, B, and C is the second functional group, and R¹, R², and R³ are arbitrarily present linking groups.

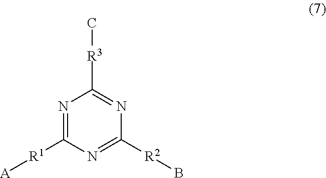

14. A method for manufacturing a storage device, comprising:
forming an opening portion on a stacked body in which conductive layers and insulating layers are alternatively stacked, the opening portion penetrates the insulating layer in a stacking direction of the stacked body and in which the conductive layer is exposed on a side surface;
forming a catalyst adsorption layer by bringing the side surface of the opening portion into contact with a solution containing an organic compound;
forming a catalyst layer on the catalyst adsorption layer; and
forming a metal layer on the catalyst layer by an electroless plating method.

15. The method for manufacturing a storage device according to claim 14, wherein the organic compound has at least one first functional group selected from the group consisting of an amino group, a thiol group, a carboxy group, and an azide group, and the organic compound has one or less aromatic ring.

16. The method for manufacturing a storage device according to claim 15, wherein the organic compound has a second functional group, and the second functional group is one a silanol group and an alkoxysilyl group.

17. The method for manufacturing a storage device according to claim 15, wherein the organic compound is represented by any one of the following formulas (1) to (6),
in the following formula (1), n is an integer of one or more and eleven or less, m is an integer of zero or more and two or less, and R is any one of H, CH₃, and CH₃CH₂,
in the following formula (2), n is an integer of one or more and eleven or less, m is an integer of zero or more and two or less, and R is any one of H, CH₃, and CH₃CH₂,
in the following formula (3), n is an integer of one or more and five or less, m is an integer of zero or more and two or less, and R is any one of H, CH₃, and CH₃CH₂,
in the following formula (4), n is an integer of zero or more and two or less, m is an integer of zero or more and two or less, and R is any one of H, CH₃, and CH₃CH₂,
in the following formula (5), n is an integer of one or more and six or less, m is an integer of zero or more and two or less, and R is any one of H, CH₃, and CH₃CH₂, and
in the following formula (6), n is an integer of one or more and four or less, m is an integer of zero or more and two or less, and R is any one of H, CH₃, and CH₃CH₂.

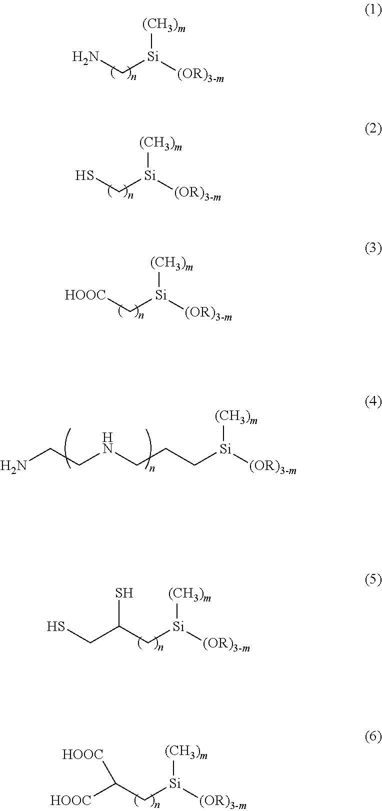

18. The method for manufacturing a storage device according to claim 16, wherein the organic compound is represented by the following formula (7), at least one of A, B, and C in the formula (7) is the first functional group, at least one of A, B, and C is the second functional group, and R¹, R², and R³ are arbitrarily present linking groups. [chemical structure]
